(19) United States
(12) Patent Application Publication
(10) Pub. No.: US 2025/0160124 A1
(43) Pub. Date: May 15, 2025

(54) FLEXIBLE DISPLAY PANEL AND METHOD FOR MANUFACTURING SAME

(71) Applicant: SHENZHEN CHINA STAR OPTOELECTRONICS SEMICONDUCTOR DISPLAY TECHNOLOGY CO., LTD., Shenzhen (CN)

(72) Inventors: Baixiang HAN, Shenzhen (CN); Zhenyang QIAO, Shenzhen (CN); Xiang YIN, Shenzhen (CN)

(21) Appl. No.: 17/641,553

(22) PCT Filed: Jan. 20, 2022
(86) PCT No.: PCT/CN2022/072923

§ 371 Date: Jan. 27, 2025

(30) Foreign Application Priority Data
Jan. 13, 2022 (CN) 202210034489.9

(51) Int. Cl. H10K 59/122; H10K 59/12; H10K 102/00

(52) U.S. Cl. CPC H10K 59/122; H10K 59/1201; H10K 2102/311

(57) ABSTRACT

The embodiments of the present application disclose a flexible display panel and a method of manufacturing the same. By providing a recess on a position of a pixel definition layer corresponding to a region between two adjacent sub-pixel regions, the recess can increase a contact area between a second electrode and the pixel definition layer, thereby improving adhesion force of the second electrode and avoiding image abnormality caused by the second electrode being peeled off from the pixel definition layer during bending of the flexible display panel.

### BACKGROUND OF DISCLOSURE

### Field of Disclosure

The present application relates to the field of display, in particular to a flexible display panel and a method for manufacturing the same.

### Description of Prior Art

Organic light-emitting diodes (OLEDs) are also referred to as organic electric laser displays or organic light-emitting semiconductors. The OLED belongs to a current-type organic light-emitting device having a phenomenon of luminescence by carrier injection and compounding, and a luminous intensity is proportional to injected current. The OLED includes an anode, a light-emitting layer, and a cathode. Under the action of an electric field, holes generated by the anode and electrons generated by the cathode move and are injected into a hole transport layer and an electron transport layer, respectively, and migrate to the light-emitting layer. When the holes and electrons meet in the light-emitting layer, energy excitons are generated, thereby exciting light-emitting molecules to eventually produce visible light.

Compared to conventional liquid crystal displays (LCDs), OLED displays have excellent characteristics such as no backlight, low drive voltage, light weight and thinness, wide viewing angles, high contrast, a fast response rate, and bendability, and are considered as the next generation of novelty application technology for flat panel displays.

A bendable nature of the OLED displays allows more optimized space and playability in display form and portability. However, when the OLED displays are bent multiple times, a phenomenon of peeling off easily occurs between the cathode and a pixel definition layer, affecting normal use of the OLED displays.

### SUMMARY OF DISCLOSURE

### Technical Problems

The embodiments of the present application provide a flexible display panel and a method for manufacturing the same, which may solve a technical problem that a phenomenon of peeling off easily occurs between a cathode and a pixel definition layer of an OLED display after being bent multiple times.

### Technical Solutions

An embodiment of the present application provides a flexible display panel, comprising:

A substrate having a plurality of sub-pixel regions;

A plurality of first electrodes disposed on one side of the substrate, each of the first electrodes corresponding to one of the sub-pixel regions;

A pixel definition layer covering the first electrode and provided with a pixel opening and a recess, the pixel opening exposing a corresponding first electrode and the recess located between adjacent two of the sub-pixel regions;

A light-emitting functional layer disposed in a corresponding pixel opening; and

A second electrode disposed on the light-emitting functional layer and the pixel definition layer, wherein the second electrode covers the recess.

Alternatively, in some embodiments of the present application, a depth of the recess is less than a thickness of the pixel definition layer.

Alternatively, in some embodiments of the present application, the depth of the recess ranges from one-fifth to two-thirds of the thickness of the pixel definition layer.

Alternatively, in some embodiments of the present application, a width of the recess in an arrangement direction of adjacent two of the sub-pixel regions is less than a spacing between adjacent two of the sub-pixel regions.

Alternatively, in some embodiments of the present application, the width of the recess in the arrangement direction of adjacent two of the sub-pixel regions ranges from one-fifth to two-thirds of the spacing between adjacent two of the sub-pixel regions.

Alternatively, in some embodiments of the present application, the recess comprises a plurality of first grooves extending in a first direction, the plurality of first grooves are arranged in a second direction, and the first direction intersects with the second direction.

Alternatively, in some embodiments of the present application, the recess further comprises a plurality of second grooves extending in the second direction, the plurality of second grooves are arranged in the first direction, and the first grooves are communicatively connected with the second grooves.

Alternatively, in some embodiments of the present application, the first direction is perpendicular to the second direction, and the plurality of sub-pixel regions are arranged in an array in the first direction and the second direction.

Alternatively, in some embodiments of the present application, the recess includes a plurality of holes.

Alternatively, in some embodiments of the present application, a shape of a cross section of the hole is circular or polygonal.

Alternatively, in some embodiments of the present application, the recess has a bottom surface and a side wall connected to the bottom surface, a first undercut opening is disposed on the side wall, the first undercut opening is communicatively connected with the recess, and the second electrode is filled within the first undercut opening.

Alternatively, in some embodiments of the present application, the pixel definition layer is further provided with a first protrusion, the protrusion is disposed in the recess, and the second electrode covers the first protrusion.

Alternatively, in some embodiments of the present application, a second undercut opening is disposed on a side surface of the first protrusion, and the second electrode is filled within the second undercut opening.

Alternatively, in some embodiments of the present application, the pixel definition layer is further provided with a second protrusion, the second protrusion is located between adjacent two of the sub-pixel regions and disposed to keep away from the recess, and the second electrode covers the second protrusion.

Alternatively, in some embodiments of the present application, a third undercut opening is disposed on a side surface of the second protrusion, and the second electrode is filled within the third undercut opening.

Alternatively, in some embodiments of the present application, the flexible display panel further comprises a drive circuit layer, the drive circuit layer is disposed between the substrate and the first electrode, wherein the drive circuit layer is provided with a plurality of thin film transistors, the plurality of thin film transistors are in a one-to-one correspondence with the sub-pixel regions, and each of the thin film transistors is electrically connected to the first electrode of a corresponding sub-pixel region.

An embodiment of the present application further provides a method of manufacturing a flexible display panel, comprising following steps:

Forming a first electrode on a substrate, the substrate having a plurality of sub-pixel regions, wherein the first electrode corresponds to the sub-pixel region;

Forming a pixel definition layer on the first electrode, the pixel definition layer being provided with a pixel opening exposing a corresponding first electrode and a recess located between adjacent two of the sub-pixel regions;

Forming a light-emitting functional layer in the pixel opening;

Forming a second electrode on the light-emitting functional layer and the pixel definition layer, wherein the second electrode covers the recess.

Wherein, in the step of forming the pixel definition layer on the first electrode, the recess comprises a plurality of first grooves extending in a first direction and arranged in a second direction, and the first direction intersects with the second direction.

Wherein, in the step of forming the pixel definition layer on the first electrode, the recess further comprises a plurality of second grooves extending in the second direction and arranged in the first direction, and the first groove is communicatively connected with the second groove.

Wherein, in the step of forming the pixel definition layer on the first electrode, the recess comprises a plurality of holes.

### Beneficial Effects

The embodiments of the present application provide a flexible display panel and a method of manufacturing the same, in which a recess is disposed on a location of a pixel definition layer corresponding to a position between two adjacent sub-pixel regions, and a second electrode is disposed on the pixel definition layer and covers the recess. The recess can increase a contact area between the second electrode and the pixel definition layer, thereby improving adhesion force of the second electrode, and avoiding image abnormality caused by peeling of the second electrode from the pixel definition layer during bending of the flexible display panel. In addition, the recess can also function as a stress relieving means to avoid the case where the film layer breaks due to stress concentration during bending of the flexible display panel.

### DESCRIPTION OF DRAWINGS

In order to more clearly explain the technical solutions in the embodiments of the present application, the following will briefly introduce the drawings required in the description of the embodiments. Obviously, the drawings in the following description are only some embodiments of the present application. For those skilled in the art, without paying any creative work, other drawings can be obtained based on these drawings.

FIG. 1 is a longitudinal sectional structural schematic view of a first flexible display panel provided by an embodiment of the present application.

FIG. 2 is a first cross-sectional structural schematic view, taken along a line A-A of FIG. 1, of a first flexible display panel provided by an embodiment of the present application.

FIG. 3 is a second cross-sectional structural schematic view, taken along the line A-A of FIG. 1, of a first flexible display panel provided by an embodiment of the present application;

FIG. 4 is a longitudinal sectional structural schematic view of a second flexible display panel provided by an embodiment of the present application;

FIG. 5 is a first cross-sectional structural schematic view, taken along a line B-B of FIG. 4, of a second flexible display panel provided by an embodiment of the present application;

FIG. 6 is a second cross-sectional structural schematic view, taken along the line B-B of FIG. 4, of a second flexible display panel provided by an embodiment of the present application;

FIG. 7 is a schematic flowchart of a method of manufacturing a flexible display panel provided by an embodiment of the present application;

FIG. 8 is a schematic diagram of manufacturing a pixel definition layer of a first flexible display panel provided by an embodiment of the present application;

FIG. 9 is a first schematic diagram of manufacturing a pixel definition layer of a second flexible display panel provided by an embodiment of the present application;

FIG. 10 is a second schematic diagram of manufacturing a pixel definition layer of a second flexible display panel provided by an embodiment of the present application;

FIG. 11 is a third schematic diagram of manufacturing a pixel definition layer of a second flexible display panel provided by an embodiment of the present application.

### DETAILED DESCRIPTION OF EMBODIMENTS

Technical solutions in embodiments of the present application will be clearly and completely described below in conjunction with drawings in the embodiments of the present application. Obviously, the described embodiments are only a part of embodiments of the present application, rather than all the embodiments. Based on the embodiments in the present application, all other embodiments obtained by those skilled in the art without creative work fall within the protection scope of the present application. In addition, it should be understood that the specific implementations described here are only used to illustrate and explain the present application, and are not used to limit the present application. In the present application, unless otherwise stated, directional words used such as “upper” and “lower” generally refer to the upper and lower directions of the device in actual use or working state, and specifically refer to the drawing directions in the drawings; and “inner” and “outer” refer to the outline of the device.

Embodiments of the present application provide a flexible display panel and a method of manufacturing the flexible display panel. The following are described in detail separately. It should be noted that the order in which the following embodiments are described is not intended to be a limitation on the preferred order of embodiments.

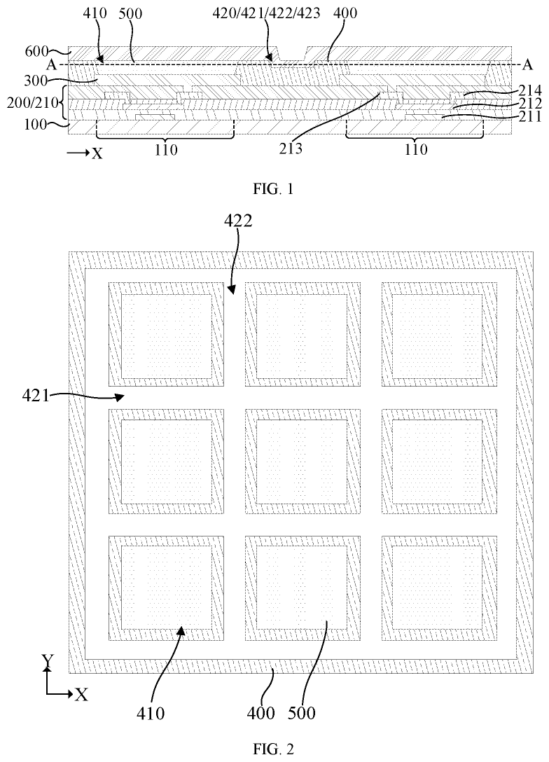

Referring to FIG. 1, an embodiment of the present application provides a flexible display panel comprising a substrate 100 and a plurality of first electrodes 300. The substrate 100 has a plurality of sub-pixel regions 110, each of the sub-pixel regions 110 includes a light-emitting region and a non-light-emitting region. The first electrode 300 is disposed on one side of the substrate 100 and the first electrode 300 corresponds to the light-emitting region of the sub-pixel region 110. In an embodiment of the present, each sub-pixel region 110 corresponds to one of the first electrodes 300.

The flexible display panel further comprises a pixel definition layer 400, the pixel definition layer 400 covers the first electrode 300. The pixel definition layer 400 is provided with a pixel opening 410 and a recess 420. The pixel opening 410 exposes a corresponding first electrode 300, i.e., the pixel opening 410 is defined corresponding to the light-emitting region of the sub-pixel region 110. The recess 420 is located between two adjacent sub-pixel regions 110. In an embodiment of the present application, the pixel definition layer 400 is provided with a plurality of pixel openings 410 and a plurality of recesses 420, and the pixel openings 410 are in a one-to-one correspondence with the sub-pixel regions 110, each of the pixel openings 410 exposes a first electrode 300 of a corresponding sub-pixel region 110.

The flexible display panel further comprises a light-emitting functional layer 500, the light-emitting functional layer 500 is disposed in a corresponding pixel opening 410. In an embodiment of the present application, the pixel definition layer 400 is provided with a plurality of pixel openings 410, and each of the pixel openings 410 is provided with a corresponding light-emitting functional layer 500.

The flexible display panel further comprises a second electrode 600, the second electrode 600 is disposed on the light-emitting functional layer 500 and the pixel definition layer 400, and the second electrode 600 covers the recess 420. In the embodiments of the present application, the recess 420 is disposed at a position of the pixel definition layer 400 corresponding to an area between two adjacent sub-pixel regions 110, so that the recess 420 can increase a contact area between the second electrode 600 and the pixel definition layer 400, thereby increasing adhesion force of the second electrode 600 and avoiding the image abnormality caused by the second electrode 600 being peeled off from the pixel definition layer 400 during bending of the flexible display panel. In addition, the recess 420 can also function as a stress relieving means to avoid a case where a film layer breaks due to stress concentration during the bending of the flexible display panel.

Specifically, one of the first electrode 300 and second electrode 600 is an anode and another is a cathode. The light-emitting functional layer 500 includes a hole injection layer, a hole transport layer, a light-emitting layer, an electron transport layer, and an electron injection layer which are sequentially stacked from the anode to the cathode, wherein the hole injection layer is disposed close to the anode and the electron injection layer is disposed close to the cathode.

Specifically, as shown in FIG. 1, in order to ensure an insulating effect of the pixel definition layer 400 and prevent the first electrode 300 and the second electrode 600 from being shorted due to breakdown of the pixel definition layer 400 at the corresponding recess 420, it is preferable that a depth of the recess 420 is less than the thickness of the pixel definition layer 400. To ensure the insulating effect of the pixel definition layer 400, the depth of the recess 420 may range from one-fifth to two-thirds of the thickness of the pixel definition layer 400. For example, the depth of the recess 420 may be one-fifth, one-third, two-fifths, one-half, three-fifths, or two-thirds of the thickness of the pixel definition layer 400.

It will be understood that the depth of the recess 420 may be appropriately adjusted according to a choice of an actual situation and specific requirements, as long as the depth of the recess 420 is ensured to be greater than 0 and less than the thickness of the pixel definition layer 400, which is not uniquely limited herein.

Specifically, as shown in FIGS. 1 to 3, a width of the recess 420 in an arrangement direction of two adjacent sub-pixel regions 110 is less than a spacing between two adjacent sub-pixel regions 110, which may prevent the case that the recess 420 is filled with the light-emitting functional layer 500 due to the recess 420 being communicatively connected to the pixel opening 410. With this configuration, it may ensure that the second electrode 600 can cover the recess 420 during the manufacturing process, thereby increasing the contact area between the second electrode 600 and the pixel definition layer 400, improving the adhesion force of the second electrode 600, and avoiding the image abnormality caused by the second electrode 600 being peeled off from the pixel definition layer 400 during the bending process of the flexible display panel.

Specifically, the width of the recess 420 in the arrangement direction of the two adjacent sub-pixel regions 110 ranges from one-fifth to two-thirds of the spacing between the two adjacent sub-pixel regions 110. For example, the width of the recess 420 in the arrangement direction of the two adjacent sub-pixel regions 110 is one-fifth, one-third, two-fifths, one-half, three-fifths or two-thirds of the spacing between the two adjacent sub-pixel regions 110. Therefore, a mechanical strength of the pixel definition layer 400 between the recess 420 and the pixel opening 410 can be ensured, effectively improving reliability of the flexible display panel.

In an embodiment of the present application, as shown in FIGS. 1 and 2, the recess 420 includes a plurality of first grooves 421 extending in a first direction X, the plurality of first grooves 421 is arranged in a second direction Y, and the first direction X intersects with the second direction Y. In this embodiment, the first groove 421 extends in the first direction X to form a strip-like groove. The second electrode 600 covers the first groove 421, so that the contact area between the second electrode 600 and the pixel definition layer 400 can be greatly increased, thereby improving the adhesion force of the second electrode 600 and preventing the image abnormality due to the second electrode 600 being peeled off from the pixel definition layer 400 during bending of the flexible display panel. In addition, the first groove 421 may also cushion the stress generated when the flexible display panel is bent in the second direction Y, avoiding the case where the film layer breaks due to stress concentration during bending.

Further, as shown in FIGS. 1 and 2, the recess 420 further includes a plurality of second grooves 422 extending in the second direction Y, the plurality of second grooves 422 is arranged in the first direction X, and the first groove 421 and the second groove 422 are communicatively connected each other. In this embodiment, the second groove 422 extends in the second direction Y to form a strip-like groove. The second electrode 600 covers the second groove 422, so that the contact area between the second electrode 600 and the pixel definition layer 400 can be greatly increased, thereby improving the adhesion force of the second electrode 600 and preventing the image abnormality due to the second electrode 600 being peeled off from the pixel definition layer 400 during bending of the flexible display panel. In addition, the second groove 422 can also cushion the stress generated when the flexible display panel is bent in the first direction X, avoiding the case where the film layer breaks due to stress concentration during bending.

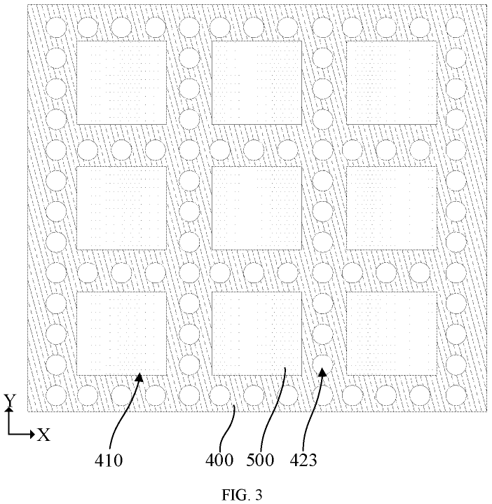

In another embodiment of the present application, as shown in FIGS. 1 and 3, the recess 420 includes a plurality of holes 423. The hole 423 is disposed between two adjacent sub-pixel regions 110, and the second electrode 600 covers the hole 423, so that the contact area between the second electrode 600 and the pixel definition layer 400 can be greatly increased, thereby improving the adhesion force of the second electrode 600 and preventing the image abnormality due to the second electrode 600 being peeled off from the pixel definition layer 400 during bending of the flexible display panel. The hole 423 can also cushion the stresses generated during bending to avoid breakage of the film layer due to stress concentration during bending of the flexible display panel.

Specifically, as shown in FIG. 3, a shape of a cross section of the hole 423 is circular. Certainly, the shape of the cross section of the hole 423 may be polygonal, such as a triangular, square, rectangular, pentagonal, and hexagonal, according to the choice of the actual situation and specific needs, which is not uniquely defined here.

Specifically, as shown in FIGS. 1 to 3, the first direction X is perpendicular to the second direction Y, and the plurality of sub-pixel regions 110 are arranged in an array in the first direction X and the second direction Y.

As shown in FIG. 2, a first groove 421 is disposed between two adjacent rows of sub-pixel regions 110, and a second groove 422 is disposed between two adjacent columns of sub-pixel regions 110. Certainly, at least two first grooves 421 may be disposed between two adjacent rows of sub-pixel regions 110, and at least two second grooves 422 may be disposed between two adjacent columns of sub-pixel regions 110, depending on the choice of the actual situation and specific needs, which is not uniquely defined here.

As shown in FIG. 3, a row of holes 423 is disposed between two adjacent rows of sub-pixel regions 110, and a column of holes 423 is disposed between two adjacent columns of sub-pixel regions 110. Certainly, at least two rows of holes 423 may be disposed between two adjacent rows of sub-pixel regions 110, and at least two columns of holes 423 may be disposed between two adjacent columns of sub-pixel regions 110, depending on the choice of the actual situation and specific needs, which is not uniquely defined here.

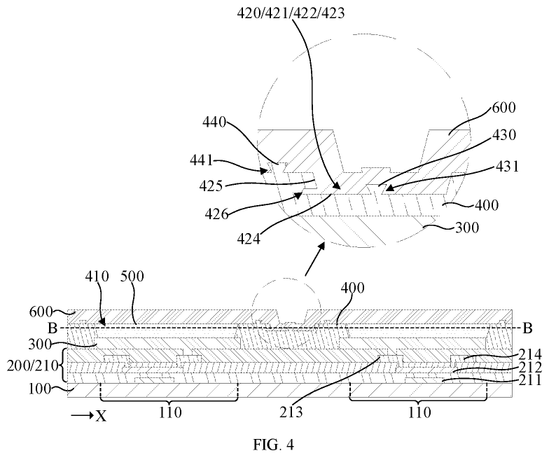

Specifically, as shown in FIGS. 4 to 6, the recess 420 has a bottom surface 424 and a side wall 425 connected to the bottom surface 424. The side wall 425 is provided with a first undercut opening 426, and the first undercut opening 426 is communicatively connected with the recess 420. The second electrode 600 is filled in the first undercut opening 426. In this configuration, the first undercut opening 426 is additionally disposed on a bottom of the recess 420 and the second electrode 600 is filled in the first undercut opening 426, so that the contact area between the second electrode 600 and the pixel definition layer 400 may be increased on one hand, thus improving the adhesion force of the second electrode 600, and on another hand, the first undercut opening 426 may avoid peeling off of the second electrode 600 from the pixel definition layer 400. With the above configuration, the image abnormality due to the second electrode 600 being peeled off from the pixel definition layer 400 during bending of the flexible display panel can be avoided.

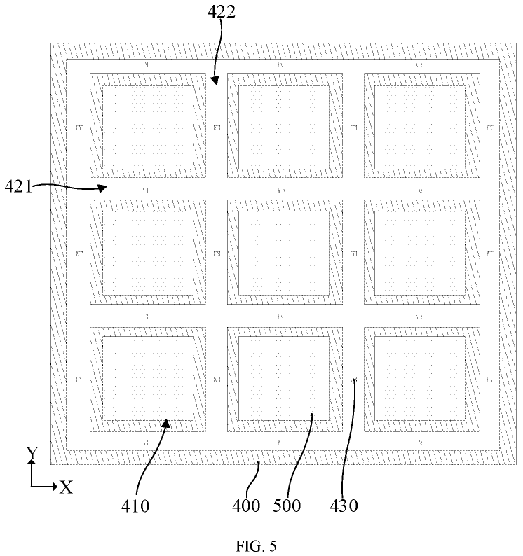

Specifically, as shown in FIGS. 4 and 5, the first groove 421 has a bottom surface 424 and two side walls 425 connected to opposite sides of the bottom surface 424. In an embodiment of the present application, one of the side walls 425 of the first groove 421 is provided with a first undercut opening 426. Certainly, both of side walls 425 of the first groove 421 may be provided with the first undercut openings 426 according to the choice of actual situation and specific requirements, which is not uniquely defined here.

Specifically, as shown in FIGS. 4 and 5, the second groove 422 has a bottom surface 424 and side walls 425 connected to opposite sides of the bottom surface 424. In an embodiment of the present application, one of the side walls 425 of the second groove 422 is provided with a first undercut opening 426. Certainly, both of side walls 425 of the second groove 422 may be provided with the first undercut openings 426 according to the choice of actual situation and specific requirements, which is not uniquely defined here.

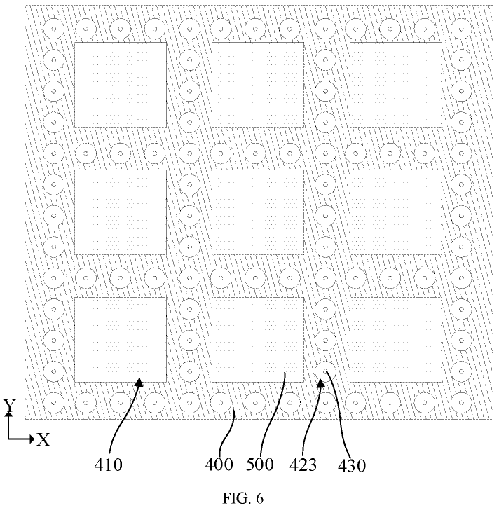

Specifically, as shown in FIGS. 4 and 6, the hole 423 has a bottom surface 424 and a side wall 425 connected to a peripheral side of the bottom surface 424. In an embodiment of the present application, the side wall 425 of the hole 423 is provided with a first undercut opening 426. Certainly, the side wall 425 of the hole 423 may be provided with two or more first undercut openings 426 according to the choice of actual situation and specific requirements, which is not defined here.

Specifically, as shown in FIGS. 4 to 6, the pixel definition layer 400 is further provided with a first protrusion 430, the first protrusion 430 is disposed in the recess 420 (the first groove 421, the second groove 422, and the hole 423), and the second electrode 600 covers the first protrusion 430. In this configuration, by providing the first protrusion 430 on the bottom surface 424 of the recess 420 and allowing the second electrode 600 to cover the first protrusion 430, the contact area between the second electrode 600 and the pixel definition layer 400 can be increased, thereby improving the adhesion force of the second electrode 600, avoiding image abnormality caused by peeling off of the second electrode 600 from the pixel definition layer 400 during bending of the flexible display panel. In this embodiment, the first protrusion 430 is disposed on the bottom surface 424 of the recess 420.

Specifically, as shown in FIGS. 4 to 6, the side surface of the first protrusion 430 is provided with a second undercut opening 431, and the second electrode 600 is filled in the second undercut opening 431, so that the contact area between the second electrode 600 and the pixel definition layer 400 can be increased on one hand, thus improving the adhesion force of the second electrode 600, and on another hand, the second undercut opening 431 can prevent the second electrode 600 from being peeled off from the pixel definition layer 400. With the above settings, the image abnormality caused by the second electrode 600 being peeled off from the pixel definition layer 400 during bending of the flexible display panel can be avoided.

Specifically, as shown in FIGS. 4 to 6, the pixel definition layer 400 is further provided with a second protrusion 440, the second protrusion 440 is positioned between two adjacent sub-pixel regions 110, and the second protrusion 440 is disposed to keep away from the recess 420 (the first groove 421, the second groove 422, and the hole 423), that is, the second protrusion 440 is positioned in a region outside the recess 420, and the second electrode 600 covers the second protrusion 440. In this configuration, by providing the second protrusion 440 on a region of the pixel definition layer 400 offsetting from the recess 420 (the first groove 421, the second groove 422, and the hole 423) and providing the second electrode 600 to cover the second protrusion 440, the contact area between the second electrode 600 and the pixel definition layer 400 can be increased, thereby improving the adhesion force of the second electrode 600, and preventing the image abnormality caused by the second electrode 600 being peeled off from the pixel definition layer 400 during bending of the flexible display panel.

Specifically, as shown in FIGS. 4 to 6, a side surface of the second protrusion 440 is provided with a third undercut opening 441, and the second electrode 600 is filled in the third undercut opening 441, so that the contact area between the second electrode 600 and the pixel definition layer 400 can be increased on one hand, thereby improving the adhesion force of the second electrode 600, and on another hand, the third undercut opening 441 can prevent the second electrode 600 from being peeled off from the pixel definition layer 400. With the above settings, the image abnormality caused by the second electrode 600 being peeled off from the pixel definition layer 400 during bending of the flexible display panel can be avoided.

Specifically, the flexible display panel further includes a drive circuit layer 200 disposed between the substrate 100 and the first electrode 300. The drive circuit layer 200 is provided with a plurality of thin film transistors 210, the plurality of thin film transistors 210 have a one-to-one correspondence with the sub-pixel regions 110. Each of the thin film transistors 210 is electrically connected to the first electrode 300 of the corresponding sub-pixel region 110. In this embodiment, the thin film transistor 210 has a corresponding gate electrode 211, an active layer 212 disposed over and insulated from the gate electrode 211, and a source electrode 213 and a drain electrode 214 disposed over the active layer 212. The source electrode 213 is in contact with one end of the active layer 212, the drain electrode 214 is in contact with another end of the active layer 212, and the first electrode 300 is in contact with the drain electrode 214, so that each thin film transistor 210 is electrically connected to the first electrode 300 of the corresponding sub-pixel region 110.

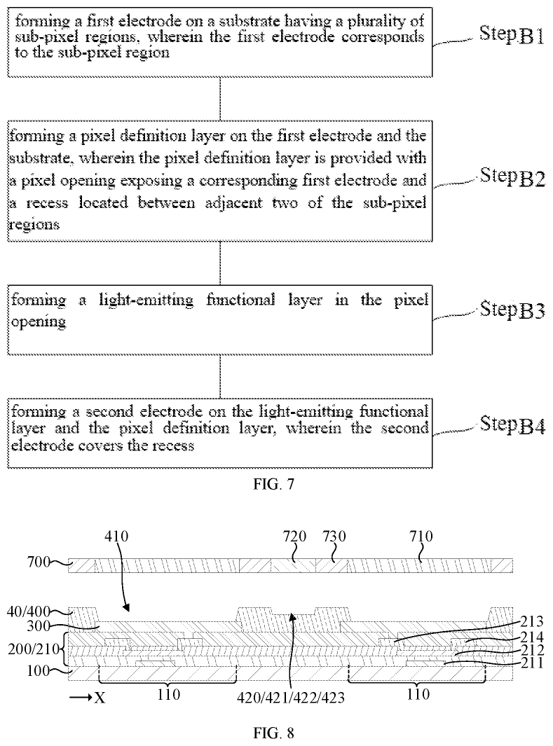

Referring to FIGS. 1, 7 and 8, an embodiment of the present application further provides a method of manufacturing the above-described flexible display panel, comprising following steps:
Step B1: a first electrode 300 is formed on a substrate 100, the substrate has a plurality of sub-pixel regions 110, and the first electrode 300 is disposed corresponding to the sub-pixel regions 110;
Step B2: a pixel definition layer 400 is formed over the first electrode 300 and the substrate 100, and the pixel definition layer 400 is provided with a pixel opening 410 and a recess 420, the pixel opening 410 exposes a corresponding first electrode 300, and the recess 420 is located between two adjacent sub-pixel regions 110;
Step B3: a light-emitting functional layer 500 is formed in the pixel opening 410;
Step B4: a second electrode 600 is formed over the light-emitting functional layer 500 and the pixel definition layer 400, and the second electrode 600 covers the recess 420. In the embodiments of the present application, the recess 420 is disposed on the position of the pixel definition layer 400 corresponding to the region between two adjacent sub-pixel regions 110. The recess 420 can increase the contact area between the second electrode 600 and the pixel definition layer 400, thereby improving the adhesion force of the second electrode 600 and avoiding the image abnormality caused by the second electrode 600 be peeled off from the pixel definition layer 400 during bending of the flexible display panel. In addition, the recess 420 can also function as a stress relieving means to avoid the case where the film layer breaks due to stress concentration during bending of the flexible display panel.

Specifically, as shown in FIG. 8, before forming the first electrode 300 on the substrate 100, the step B1 further comprises forming a drive circuit layer 200 on the substrate 100, wherein the first electrode 300 is formed on the drive circuit layer 200, and the drive circuit layer 200 is disposed between the substrate 100 and the first electrode 300. The drive circuit layer 200 is provided with a plurality of thin film transistors 210, the thin film transistors 210 and the sub-pixel regions 110 are in one-to-one correspondence, and each thin film transistor 210 is electrically connected to the first electrode 300 of the corresponding sub-pixel regions 110.

Specifically, as shown in FIG. 8, in the above step B2, the step of forming the pixel definition layer 400 on the first electrode 300 and the substrate 100 specifically comprises:
Step B21: the first electrode 300 is covered with a photoresist material layer 40 on the entire surface thereof, and a photomask 700 is used for performing exposure and development to form the pixel opening 410 and the recess 420, obtaining the pixel definition layer 400. With this arrangement, the pixel openings 410 and the recesses 420 can be simultaneously prepared by a single photomask 700, so that process efficiency can be improved, thereby effectively improving productivity and reducing the production cost.

Specifically, in step B21, the photomask 700 has a first region 710 corresponding to the sub-pixel region 110, a second region 720 corresponding to the recess 420, and a third region 730 corresponding to a region between the sub-pixel region 110 and the recess 420. When a material of the photoresist material layer 40 is a positive photoresist, light transmittance of the first region 710 is greater than light transmittance of the second region 720, and the light transmittance of the second region 720 is greater than light transmittance of the third region 730. When the material of the photoresist material layer 40 is a negative photoresist, the light transmittance of the first region 710 is less than the light transmittance of the second region 720, and the light transmittance of the second region 720 is less than the light transmittance of the third region 730.

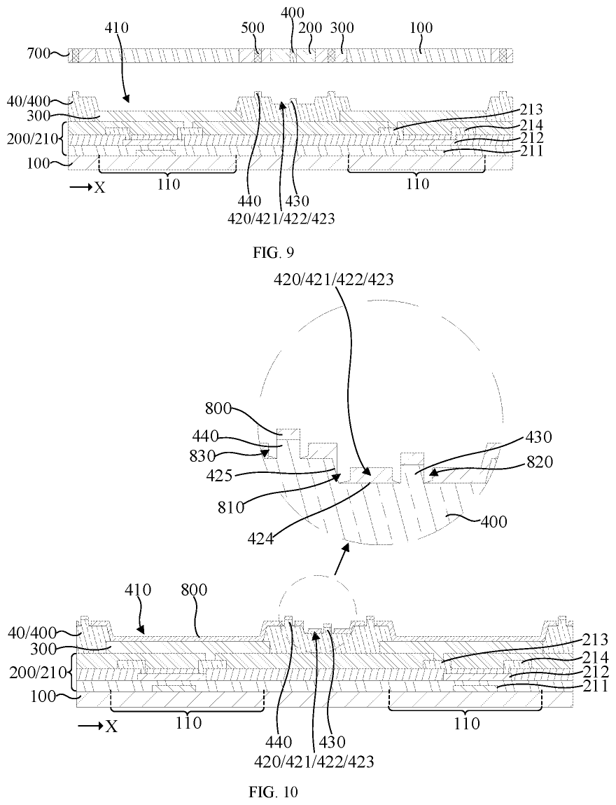

Specifically, as shown in FIGS. 4 and 9, in the above step B2, the pixel definition layer 400 is further provided with a first protrusion 430 defined in the recess 420, and the second electrode 600 formed in the subsequent step B4 covers the first protrusion 430. In this embodiment, the photomask 700 has a fourth region 740 corresponding to the first protrusion 430. When the material of the photoresist material layer 40 is a positive photoresist, light transmittance of the fourth region 740 is less than the light transmittance of the second region 720, and the light transmittance of the fourth region 740 is greater than the light transmittance of the third region 730. When the material of the photoresist material layer 40 is a negative photoresist, the light transmittance of the fourth region 740 is greater than the light transmittance of the second region 720, and the light transmittance of the fourth region 740 is less than the light transmittance of the third region 730.

Specifically, as shown in FIGS. 4 and 9, in the above-described step B2, the pixel definition layer 400 is further provided with a second protrusion 440 located between two adjacent sub-pixel regions 110, and the second protrusion 440 is disposed to keep away from the recess 420, that is, the second protrusion 440 is located outside the recess 420. The second electrode 600 formed in the subsequent step B4 covers the second protrusion 440. In this embodiment, the photomask 700 has a fifth region 750 corresponding to the second projection 440. When the material of the photoresist material layer 40 is a positive photoresist, light transmittance of the fifth region 750 is less than the light transmittance of the third region 730. When the material of the photoresist material layer 40 is a negative photoresist, the light transmittance of the fifth region 750 is greater than the light transmittance of the third region 730.

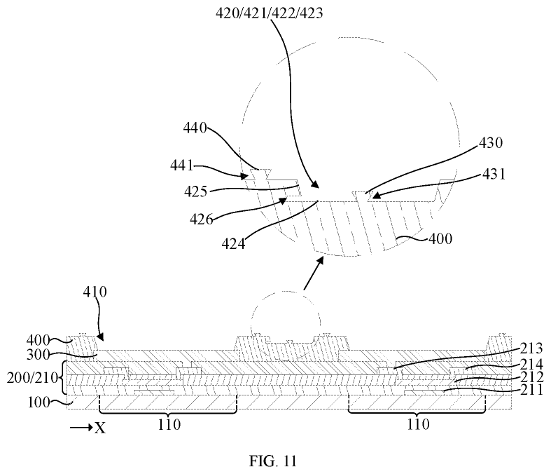

Specifically, as shown in FIGS. 4 and 10, in the above-described step B2, the recess 420 has a bottom surface 424 and a side wall 425 connected to the bottom surface 424. The side wall 425 is provided with a first undercut opening 426 communicatively connected with the recess 420, and the second electrode 600 formed in the subsequent step B4 is filled in the first undercut opening 426. In this embodiment, the step B2 further comprises:
Step B22: the pixel definition layer 400 is covered with a layer of photoresist 800, and an exposure and development process is performed on the photoresist 800, thereby forming a first notch 810 on the photoresist 800. The first notch 810 exposes the side wall 425 of the recess 420;
Step B23: a portion of the side wall 425 of the recess 420 is etched by the first notch 810 to form the first undercut opening 426;
Step B24: as shown in FIG. 11, the photoresist 800 is peeled off.

Specifically, as shown in FIGS. 4 and 10, in the above-described step B2, the side surface of the first protrusion 430 is provided with the second undercut opening 431, and the second electrode 600 formed in the subsequent step B4 is filled in the second undercut opening 431. In this embodiment, a second notch 820 is formed on the photoresist 800 after the photoresist 800 is exposed and developed in step B22, and the second notch 820 exposes the side surface of the first protrusion 430. Step B23 further comprises etching a portion of the side surface of the first protrusion 430 through the second notch 820 to form the second undercut opening 431.

Specifically, as shown in FIGS. 4 and 10, in the above-described step B2, a third undercut opening 441 is formed on the side surface of the second protrusion 440, and the second electrode 600 formed in the subsequent step B4 is filled in the third undercut opening 441. In this embodiment, a third notch 830 is formed on the photoresist 800 after the photoresist 800 is exposed and developed in step B22, and the third notch 830 exposes the side surface of the second protrusion 440. Step B23 further comprises etching a portion of the side surface of the second protrusion 440 through the third notch 830 to form the third undercut opening 441.

In an embodiment of the present application, the above-described step B23 is performed by wet etching. By adding an etching liquid into the first notch 810, the second notch 820, and the third notch 830 dropwise, bottoms of the side wall 425 of the recess 420, the side surface of the first protrusion 430, and the side surface of the second protrusion 440 can be etched to form the first undercut opening 426, the second undercut opening 431, and the third undercut opening 441, respectively.

The foregoing has described in detail a flexible display panel and a method of manufacturing the same provided in the embodiments of the present application. The principles and implementations of the present application are described with specific examples. The description of the foregoing embodiments is merely intended to help understand the method and core ideas of the present application. Meanwhile, a person skilled in the art may make changes in the specific embodiments and application scope according to the idea of the present application. In conclusion, the content of the specification should not be construed as a limitation to the present application.

1. A flexible display panel, comprising:
a substrate having a plurality of sub-pixel regions;
a plurality of first electrodes disposed on one side of the substrate, each of the first electrodes being disposed to correspond to one of the sub-pixel regions;
a pixel definition layer covering the first electrode and provided with a pixel opening and a recess, the pixel opening exposing a corresponding first electrode and the recess located between adjacent two of the sub-pixel regions;
a light-emitting functional layer disposed in a corresponding pixel opening; and
a second electrode disposed on the light-emitting functional layer and the pixel definition layer, wherein the second electrode covers the recess.

2. The flexible display panel of claim 1, wherein a depth of the recess is less than a thickness of the pixel definition layer.

3. The flexible display panel of claim 2, wherein the depth of the recess ranges from one-fifth to two-thirds of the thickness of the pixel definition layer.

4. The flexible display panel of claim 1, wherein a width of the recess in an arrangement direction of adjacent two of the sub-pixel regions is less than a spacing between adjacent two of the sub-pixel regions.

5. The flexible display panel of claim 4, wherein the width of the recess in the arrangement direction of adjacent two of the sub-pixel regions ranges from one-fifth to two-thirds of the spacing between adjacent two of the sub-pixel regions.

6. The flexible display panel of claim 1, wherein the recess comprises a plurality of first grooves extending in a first direction, the plurality of first grooves are arranged in a second direction, and the first direction intersects with the second direction.

7. The flexible display panel of claim 6, wherein the recess further comprises a plurality of second grooves extending in the second direction, the plurality of second grooves are arranged in the first direction, and the first grooves are communicatively connected with the second grooves.

8. The flexible display panel of claim 6, wherein the first direction is perpendicular to the second direction, and the plurality of sub-pixel regions are arranged in an array in the first direction and the second direction.

9. The flexible display panel of claim 1, wherein the recess includes a plurality of holes.

10. The flexible display panel of claim 9, wherein a shape of a cross section of the hole is circular or polygonal.

11. The flexible display panel of claim 1, wherein the recess has a bottom surface and a side wall connected to the bottom surface; a first undercut opening is disposed on the side wall, the first undercut opening is communicatively connected with the recess, and the second electrode is filled within the first undercut opening.

12. The flexible display panel of claim 1, wherein the pixel definition layer is further provided with a first protrusion, the protrusion is disposed in the recess, and the second electrode covers the first protrusion.

13. The flexible display panel of claim 12, wherein a second undercut opening is disposed on a side surface of the first protrusion, and the second electrode is filled within the second undercut opening.

14. The flexible display panel of claim 1, wherein the pixel definition layer is further provided with a second protrusion, the second protrusion is located between adjacent two of the sub-pixel regions and disposed to keep away from the recess, and the second electrode covers the second protrusion.

15. The flexible display panel of claim 14, wherein a third undercut opening is disposed on a side surface of the second protrusion, and the second electrode is filled within the third undercut opening.

16. The flexible display panel of claim 1, wherein the flexible display panel further comprises a drive circuit layer, the drive circuit layer is disposed between the substrate and the first electrode, wherein the drive circuit layer is provided with a plurality of thin film transistors, the plurality of thin film transistors are in a one-to-one correspondence with the sub-pixel regions, and each of the thin film transistors is electrically connected to the first electrode of a corresponding sub-pixel region.

17. A method of manufacturing a flexible display panel, comprising following steps:
forming a first electrode on a substrate, the substrate having a plurality of sub-pixel regions, the first electrode being disposed to correspond to the sub-pixel region;
forming a pixel definition layer on the first electrode, the pixel definition layer being provided with a pixel opening and a recess, the pixel opening exposing a corresponding first electrode and the recess located between adjacent two of the sub-pixel regions;
forming a light-emitting functional layer in the pixel opening;
forming a second electrode on the light-emitting functional layer and the pixel definition layer, wherein the second electrode covers the recess.

18. The method of claim 17, wherein in the step of forming the pixel definition layer on the first electrode, the recess comprises a plurality of first grooves extending in a first direction, the plurality of first grooves are arranged in a second direction, and the first direction intersects with the second direction.

19. The method of claim 18, wherein in the step of forming the pixel definition layer on the first electrode, the recess further comprises a plurality of second grooves extending in the second direction, the plurality of second grooves are arranged in the first direction, and the first grooves are communicatively connected with the second grooves.

20. The method of claim 17, wherein in the step of forming the pixel definition layer on the first electrode, the recess comprises a plurality of holes
